(19) United States
(12) Patent Application Publication
(10) Pub. No.: US 2008/0204002 A1
(43) Pub. Date: Aug. 28, 2008

(54) INCLINATION SENSOR

(75) Inventor: Izumi Kurose, Touhaku-gun (JP)

Correspondence Address: OSHA LIANG L.L.P., 1221 MCKINNEY STREET, SUITE 2800, HOUSTON, TX, 77010, US

(73) Assignee: OMRON CORPORATION, Kyoto-shi (JP)

(21) Appl. No.: 12/036,334

(22) Filed: Feb. 25, 2008

(30) Foreign Application Priority Data
Feb. 26, 2007 (JP) 2007-045666

(51) Int. Cl. G01R 33/07

(52) U.S. Cl. 324/207.2

(57) ABSTRACT

A first magnetic circuit in which a magnetic line of force flows only between a pair of permanent magnets is closed, when a rolling element is located at the stationary position. When a case is inclined to roll the rolling element to a first end portion, while a second magnetic circuit in which the magnetic line of force flows only between the rolling element and one of the permanent magnets is closed, a magnetic force detecting region detects the magnetic line of force of the other permanent magnet. When the case is inclined to roll the rolling element to a second end portion, while a third magnetic circuit in which the magnetic line of force flows only between the rolling element and the other permanent magnet is closed, the magnetic force detecting region detects the magnetic line of force of one of the permanent magnets.

### BACKGROUND OF THE INVENTION

1. Field of the Invention

The present invention relates to an inclination sensor, particularly to a compact magnetic type inclination sensor used in a digital camera, a video camera, and the like.

2. Description of the Related Art

Conventionally, for example there is an inclination sensor, wherein a rolling element formed by a permanent magnet is rolled in a rolling groove, and a magnetic line of force of the rolling element is sensed to detect an inclination of a body to be detected using a magnetic detecting element (refer to, for example, Japanese Patent Application Laid-Open No. 2001-324324).

However, because the rolling element is formed by the permanent magnet in the inclination sensor, the inclination sensor is easily affected by an external magnetic field. When an electromagnet or a magnetized metal exists around the inclination sensor, the rolling element is not smoothly rolled, and possibly the inclination state is not correctly detected.

Therefore, in order to avoid the influence of the external magnetic field, there is proposed an inclination sensor, wherein the permanent magnet is fixed to a case, a pendulum assembled to a pair of magnetic material is rotatably supported by the case, and a magnetic circuit is closed through the magnetic materials to detect the inclination state (refer to, for example, Japanese Patent Application Laid-Open No. 2006-90796).

However, in the inclination sensor disclosed in Japanese Patent Application Laid-Open No. 2006-90796, the magnetic circuit is closed while the magnetic line of force is curved to intersect a Hall IC through the magnetic materials assembled to the pendulum. The need for the magnetic line of force to pass through the magnetic materials leads to increase a space gap and a magnetic resistance. As a result, desired magnetic efficiency is hardly obtained due to easy generation of magnetic loss and low magnetic flux density. Accordingly, in the inclination sensor disclosed in Japanese Patent Application Laid-Open No. 2006-90796, when the magnetic line of force having the desired magnetic flux density is caused to pass through the magnetic materials, it is necessary to dispose the large permanent magnet, which results in problems of difficulty of downsizing of the apparatus, a large number of components, many assembling man-hour, and low productivity.

In view of the foregoing, an object of the invention is to provide a compact and high-productivity inclination sensor having good magnetic efficiency.

### SUMMARY OF THE INVENTION

In accordance with an aspect of the invention, an inclination sensor includes a box-shaped base in which a rolling groove is formed in an inner bottom surface, the rolling groove being extended toward two directions from a stationary position, the rolling groove having first and second end portions at a front end portion thereof; a rolling element which is rotatably accommodated in the rolling groove, the rolling element being made of a magnetic material; a pair of permanent magnets which is disposed at positions adjacent to the first and second end portions, the permanent magnets being disposed such that facing magnetic pole surfaces differ from each other; and a Hall IC which is disposed between the permanent magnets, the Hall IC having a magnetic force detecting region in a center thereof, wherein, when the rolling element is located at the stationary position, a first magnetic circuit in which a magnetic line of force flows only between the pair of permanent magnets is closed, when the case is inclined to roll the rolling element to the first end portion, while a second magnetic circuit in which the magnetic line of force flows only between the rolling element and one of the permanent magnets is closed, the magnetic force detecting region detects the magnetic line of force of the other permanent magnet, when the case is inclined to roll the rolling element to the second end portion, while a third magnetic circuit in which the magnetic line of force flows only between the rolling element and the other permanent magnets is closed, the magnetic force detecting region detects the magnetic line of force of one of the permanent magnets, whereby different detection outputs are outputted according to a direction in which the case is inclined.

According to the invention, when the rolling element made of the magnetic material is rolled to one of the first and second end portions in the rolling groove, while a second magnetic circuit in which the magnetic line of force flows only between the rolling element and one of the pair of permanent magnets disposed adjacent to the first and second end portion is closed, the first magnetic circuit closed only between the pair of permanent magnets is eliminated. At the same time, a third magnetic circuit in which the magnetic line of force flows only between the other permanent magnet and the magnetic force detecting region of the Hall IC is closed, and the magnetic line of force of the other permanent magnet flows directly through the Hall IC. Accordingly, the space gap between the other permanent magnet and the magnetic force detecting region of the Hall IC is decreased and the magnetic resistance is decreased. Therefore, the magnetic loss is decreased and the magnetic line of force of the permanent magnet is utilized while waste is eliminated, so that the inclination sensor having the good magnetic efficiency can be obtained. Because the magnetic efficiency is improved, it is not necessary to use the large permanent magnet is not required, and it is not necessary to assemble magnetic material to the pendulum unlike the conventional technique. Therefore, according to the aspect of the invention, the compact inclination sensor having the small number of components and few assembling man-hour is obtained.

In the inclination sensor according to the aspect of the invention, preferably the rolling element is formed in a spherical shape. Accordingly, the spherical rolling element has small friction, and particularly the friction of the spherical rolling element is about one-tenth the friction generated between the pendulum and rotating shaft portion in the conventional technique. Therefore, a variation in operation characteristic caused by the friction is decreased to obtain the high-reliability inclination sensor. Unlike the conventional technique, it is not necessary that the pendulum and the magnetic material be formed by the different parts, and the small number of components and few assembling man-hour are achieved in the inclination sensor of the invention, so that the productivity can be enhanced to reduce the cost. Particularly the assembling work of the pendulum and the magnetic material, in which high assembling accuracy is required, is eliminated, so that the productivity is further improved.

### BRIEF DESCRIPTION OF THE DRAWINGS

FIG. 1 is a perspective view showing an inclination sensor according to an embodiment of the invention;

FIG. 2 is an exploded perspective view showing the inclination sensor of FIG. 1;

FIG. 3A, is a perspective view showing the inclination sensor before operation, FIG. 3B is a front view showing the inclination sensor before operation, and FIG. 3C is a sectional view taken on a line C-C of FIG. 3B;

FIG. 4A, is a perspective view showing the inclination sensor after operation, FIG. 4B is a front view showing the inclination sensor after operation, and FIG. 4C is a sectional view taken on a line C-C of FIG. 4B; and

FIG. 5A is a front view showing the inclination sensor of the embodiment and FIG. 5B is a timing chart.

### DETAILED DESCRIPTION OF THE PREFERRED EMBODIMENTS

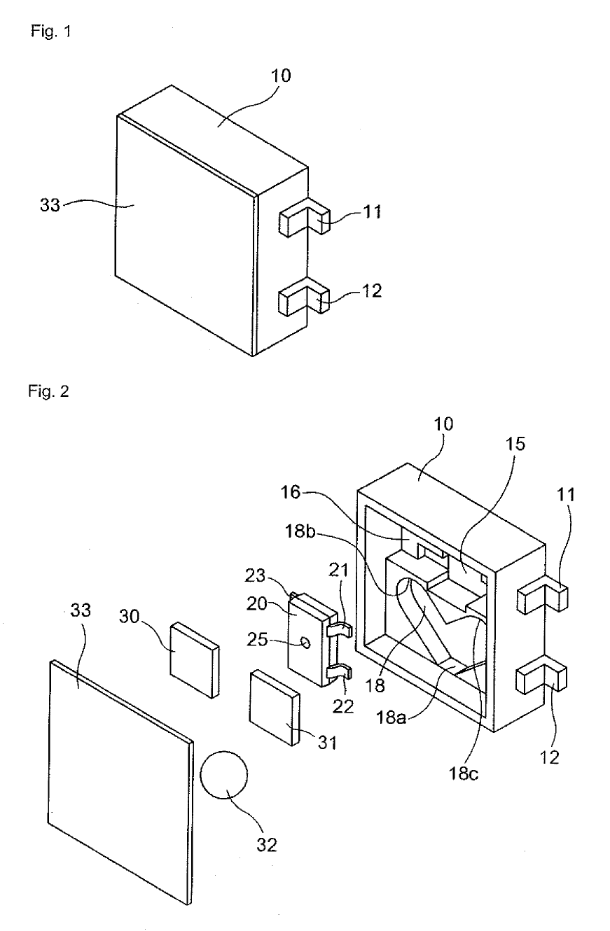

An inclination sensor according to an embodiment of the invention will described with reference to FIGS. 1 to 5. The inclination sensor of the embodiment includes a case 10, a Hall IC 20 which is of magnetic force detecting means, a pair of permanent magnets 30 and 31, a spherical rolling element 32 which is made of a magnetic material, and a cover 33. A main body of the inclination sensor of the embodiment has a width of 5 mm, a height of 5 mm, and a thickness of 2 mm. The spherical rolling element 32 has a diameter of 1.2 mm.

The case 10 is a resin molding product having a box-shape whose front view is a substantially square. Power terminals 11 and 13 and signal terminals 12 and 14 are insert-molded in sidewalls facing on both sides, respectively. In the case 10, a center recess 15 is formed in the center of an upper half of the front face to assemble the Hall IC 20 thereto. Recesses 16 and 17 are formed on both sides of the center recess 15 to dispose permanent magnets 30 and 31 respectively. Connecting end portions of the terminals 11, 12, 13, and 14 are exposed to a bottom surfaces of the recesses 16 and 17 respectively. A rolling groove 18 formed in a substantially V-shape is provided in a lower half of the case 10. The rolling groove 18 is extended toward different directions from a stationary position 18a provided in the center, namely, a first end portion 18b is extended to the neighborhood of the recess 16 while a second end portion 18c is extended to the neighborhood of the recess 17.

A Hall element which is of a magnetic sensor and IC which converts an output signal of the Hall element into a digital signal are packaged in the Hall IC 20. In the Hall IC 20, power terminals 21 and 23 and signal terminals 22 and 24 are insert-molded in sidewalls facing on both sides, respectively. A magnetic force detecting region 25 is disposed in a central portion of the Hall IC 20. In the magnetic force detecting region 25, the Hall element built-in the Hall IC 20 can detect the magnetic force. The Hall IC 20 is disposed in the center recess 15 of the case 10 to connect the terminals 21, 22, 23, and 24 to the terminals 11, 12, 13, and 14 of the case 10 respectively, and the signal terminals 12 and 14 constitute output terminals of the inclination sensor.

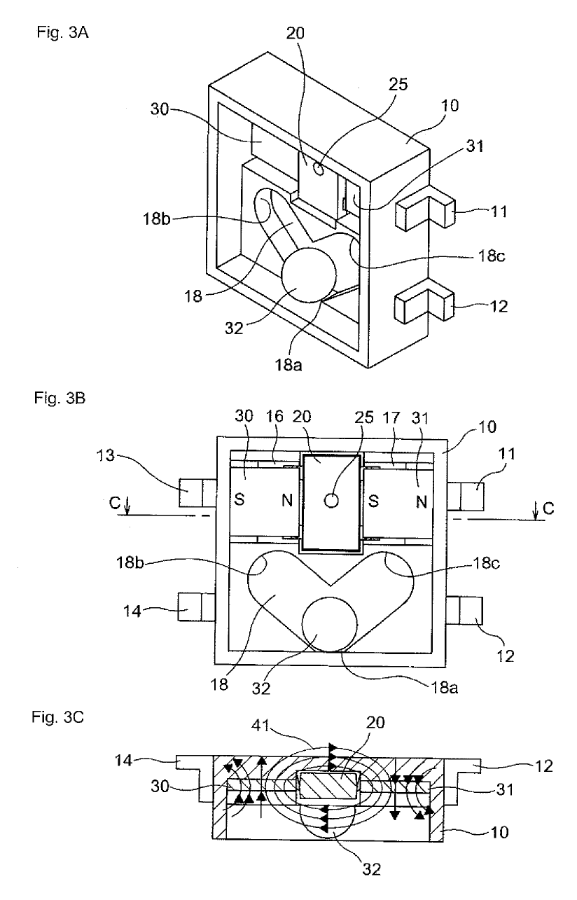

The permanent magnets 30 and 31 have front face shapes which can be fitted in the recesses 16 and 17 of the case 10 respectively. The permanent magnets 30 and 31 are assembled such that an S pole and an N pole face the recesses 16 and 17 of the case 10. Therefore, the magnetic lines of forces of the permanent magnets 30 and 31 flow in directions in which the magnetic lines of forces are not detected by the magnetic force detecting region 25 of the Hall IC 20, namely, the magnetic lines of forces flow in parallel with the surface of the Hall IC 20 to form a first closed magnetic circuit 41 (FIG. 3C).

The rolling element 32 is a spherical magnetic material having an outer diameter which can be rotatably accommodated in the rolling groove 18, and the rolling element 32 rests at the stationary position 18a of the rolling groove 18. The rolling element 32 is not limited to the spherical shape, but the rolling element 32 may be formed in a cylindrical shape. When the rolling element 32 has the cylindrical shape, the rolling element 32 can be produced by cutting a rod-shape magnetic material, and advantageously the rolling element 32 is easily produced and cost is reduced.

The cover 33 has a front face shape with which an opening edge portion of the case 10 is covered, and is fixed to the opening edge portion of the case 10 to prevent drop-off of the spherical rolling element 32.

An operation of the inclination sensor including the components will be described below. As shown in FIG. 3, when the inclination sensor stands upright, the spherical rolling element 32 rests at the stationary position 18a of the rolling groove 18. Therefore, the magnetic line of force flowing only between the permanent magnets 30 and 31 acts parallel to the surface of the Hall IC 20, and the magnetic line of force does not intersect the magnetic force detecting region 25 of the Hall IC 20.

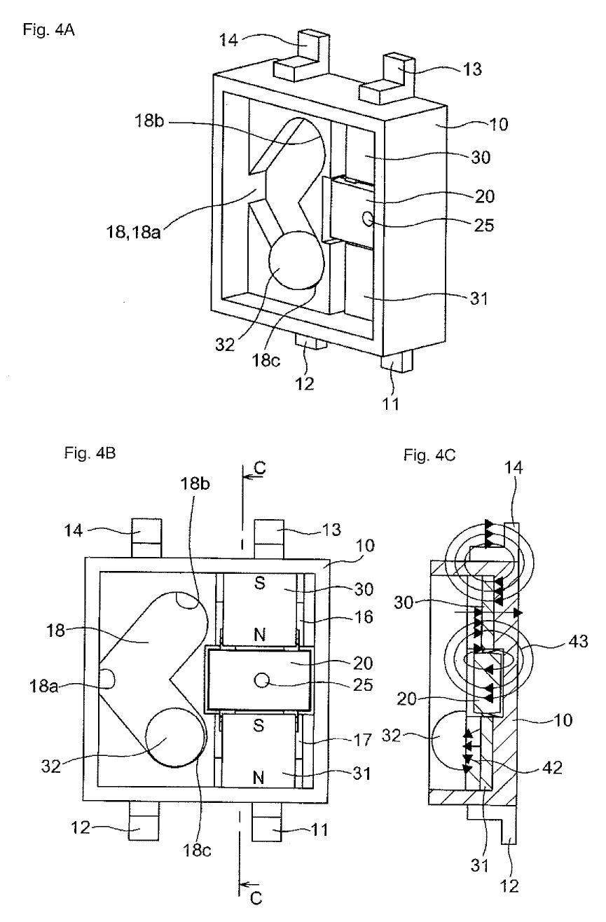

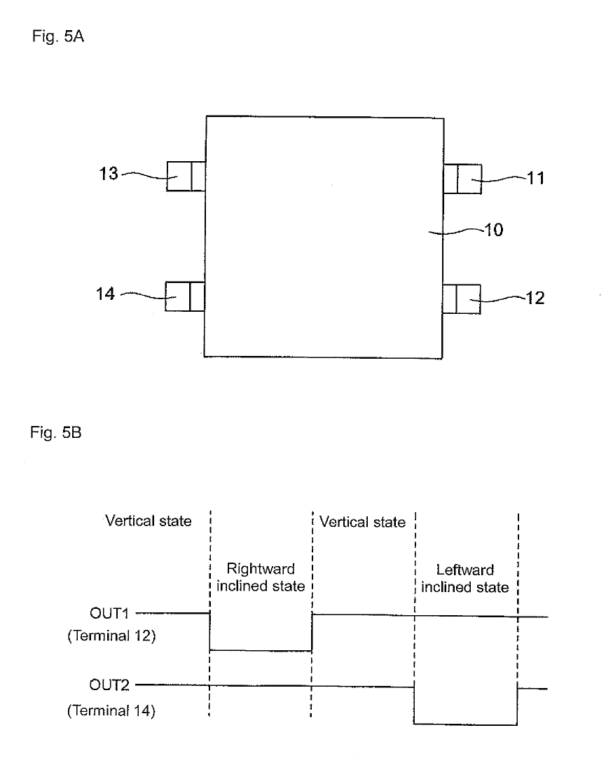

As shown in FIG. 4, when the inclination sensor is inclined rightward by 90 degrees, the rolling element 32 is rolled from the stationary position 18a of the rolling groove 18 to the second end portion 18c, and the rolling element 32 is brought close to the permanent magnet 31. This enables the magnetic line of force of the permanent magnet 31 to flow between the rolling element 32 and the permanent magnet 31 to close a second magnetic circuit 42. Therefore, the magnetic line of force of the permanent magnet 30 flows so as to intersect the magnetic force detecting region 25 of the Hall IC 20, a third magnetic circuit 43 is closed, and the magnetic line of force acts in a clockwise direction in FIG. 4C, whereby the Hall IC 20 outputs the detection signal from the signal terminal 12 (FIG. 5B).

Then, when the inclination sensor is raised, the rolling element 32 returns to the stationary position 18a of the rolling groove 18. Therefore, the magnetic line of force flows only between the permanent magnets 30 and 31 to close the first magnetic circuit 41 through which the magnetic line of force flows in parallel with the surface of the Hall IC 20, which stops the output of the detection signal from the Hall IC 20.

When the inclination sensor is inclined leftward by 90 degrees, the rolling element 32 is rolled from the stationary position 18a of the rolling groove 18 to the first end portion 18b and, similarly to the case in which the inclination sensor is inclined rightward, the magnetic line of force of the permanent magnet 30 flows so as to intersect the magnetic force detecting region 25 of the Hall IC 20. At this point, the magnetic line of force is formed in the direction opposite to that (clockwise direction) of the case in which the inclination sensor is inclined rightward, and the Hall IC 20 outputs the detection signal from the signal terminal 12 (FIG. 5B). That is, the output in leftward inclining the inclination sensor and the output in leftward inclining the inclination sensor can be detected while clearly distinguished from each other.

The inclination sensor of the embodiment outputs the detection signal by rolling the spherical rolling element, and the rolling friction thereof is about one-tenth the sliding friction. Therefore, the inclination sensor having the good responsibility, troubleproof property and high durability is obtained.

In the embodiment, the permanent magnets 30 and 31 and the Hall IC are disposed in the substantially same plane. Alternatively, one of the permanent magnets 30 and 31 and the Hall IC is shifted in the thickness direction, and may be disposed so as to partially overlap each other.

Obviously the inclination sensor according to the invention can also be applied to not only the inclination sensor but also other inclination sensors.

What is claimed is:

1. An inclination sensor comprising:
a box-shaped base in which a rolling groove is formed in an inner bottom surface, the rolling groove being extended toward two directions from a stationary position, the rolling groove having first and second end portions at a front end portion thereof;
a rolling element which is rotatably accommodated in the rolling groove, the rolling element being made of a magnetic material;
a pair of permanent magnets which is disposed at positions adjacent to the first and second end portions, the permanent magnets being disposed such that facing magnetic pole surfaces differ from each other; and
a Hall IC which is disposed between the permanent magnets, the Hall IC having a magnetic force detecting region in a center thereof,
wherein, when the rolling element is located at the stationary position, a first magnetic circuit in which a magnetic line of force flows only between the pair of permanent magnets is closed,
when the case is inclined to roll the rolling element to the first end portion, while a second magnetic circuit in which the magnetic line of force flows only between the rolling element and one of the permanent magnets is closed, the magnetic force detecting region detects the magnetic line of force of the other permanent magnet,
when the case is inclined to roll the rolling element to the second end portion, while a third magnetic circuit in which the magnetic line of force flows only between the rolling element and the other permanent magnet is closed, the magnetic force detecting region detects the magnetic line of force of one of the permanent magnets,
whereby different detection outputs are outputted according to a direction in which the case is inclined.

2. The inclination sensor according to claim 1, wherein the rolling element is formed in a spherical shape.
